(19) United States
(12) Patent Application Publication
(10) Pub. No.: US 2014/0158295 A1
(43) Pub. Date: Jun. 12, 2014

(54) Erosion Resistant Wellbore Screen and Associated Methods of Manufacture

(71) Applicant: WEATHERFORD/LAMB, INC., Houston, TX (US)

(72) Inventor: Robert P. Badrak, Sugar Land, TX (US)

(73) Assignee: WEATHERFORD/LAMB, INC., Houston, TX (US)

(21) Appl. No.: 13/709,926

(22) Filed: Dec. 10, 2012

(51) Int. Cl. E21B 43/08; C23C 14/35; C23C 16/44; B32B 37/14; C23C 4/12; C23C 16/50

(52) U.S. Cl. CPC E21B 43/088; C23C 4/127; C23C 4/124; C23C 4/125; C23C 4/12; C23C 16/50; C23C 16/44; B32B 37/14; C23C 14/35
USPC 156/307.1; 427/248.1; 427/446; 427/450; 427/452; 427/249.8; 427/249.1; 427/427.4; 427/177; 427/560; 427/555; 156/60; 427/569; 204/192.12

(57) ABSTRACT

A method of manufacturing or surface treating a wire wrapped screen for use in a wellbore improves the erosion resistance of the wire-wrapped screen. The wire-wrapped screen can be disposed on an axle positioned in a chamber containing a source of erosion resistant surface coating. The coating is then deposited on the exterior of the wire-wrapped screen using a deposition process, such as physical vapor deposition or thermal spraying. Alternatively, a spray system proximate the wire-wrapped screen can have a deposition nozzle to coat the exterior surface of the screen with an elastomer coating by spraying an elastomer. In additional embodiments, the wire for the wire-wrapped screen can first be treated for erosion resistance and then wound about a mandrel to form the wire-wrapped screen.

### BACKGROUND OF THE DISCLOSURE

Subterranean filters, also known as “sand screens” or “well screens,” have been used in the petroleum industry for years to remove particulates from production fluids. The well screens have a perforated inner pipe and at least one porous filter layer wrapped around and secured to the pipe. Typically, the wellscreen is deployed on a production string, and produced fluid passes through the filter layer and into the perforated pipe to be produced to the surface.

For example, a completion system 10 in FIG. 1 has completion screen joints 50 deployed on a completion string 14 in a borehole 12. Typically, these screen joints 50 are used for horizontal and deviated boreholes passing in an unconsolidated formation as noted above, and packers 16 or other isolation elements can be used between the various joints 50. During production, fluid produced from the borehole 12 pass through the screen joints 50 and up the completion string 14 to the surface rig 18. The screen joints 50 keep out fines and other particulates in the produced fluid. In this way, the screen joints 50 can mitigate damage to components, mud caking in the completion system 10, and other problems associated with fines, particulate, and the like present in the produced fluid.

One type of wellscreen is a wire-wrapped screen. The two typical types of wire-wrapped screens include slip-on screens and direct-wrap screens. A slip-on screen is manufactured by wrapping a screen jacket on a machined mandrel. Then, the jacket is later slipped on a base pipe, and the end of the jacket is attached to the base pipe, typically by welding. An example of how one type of slip-on screen is manufactured by heating and shrink fitting is disclosed in U.S. Pat. No. 7,690,097.

The slip-on screen may allow for precise slots to be constructed, but the screen is inherently weaker than a direct-wrap screen. Discrepancies in the slip-on screen, such as variations in the spacing between the screen jacket and the base pipe, can be problematic. For example, differential pressure usually exists across the slip-on screen when in service, and sufficient differential pressure can cause the wires and the rods to bend inwardly into contact with the base pipe. Such a collapse will result in a shifting of the coils of wire forming the screen and reduce or destroy its ability to serve its intended purpose.

The direct-wrap screen is constructed by wrapping the screen directly on the perforated base pipe. As expected, this results in a stronger screen because any annulus between the screen jacket and the base pipe is eliminated. FIGS. 2A-2B show an apparatus 60 for constructing a wire-wrapped screen in place directly on a base pipe 52. Spaced around the outside of the base pipe 52, a number of rods 56 extend along the pipe's outside surface. The apparatus 60 wraps the wire 58 around the pipe 52 and the rods 56 to form a screen jacket. A drum (not shown) and other wire feeding components known in the art feed the wire 58 as it is being wrapped, and these components usually hold the wire in tension to bend around the pipe 52 and the rods 56.

To wrap the wire 58, the pipe 52 and rods 56 are typically rotated relative to the apparatus 60. At the same time, the pipe 52 and rods 56 are moved longitudinally at a speed that provides a desired spacing between the adjacent coils of wire 58. This spacing is commonly referred to as the “slot.” Alternatively, the apparatus 60 can be moved longitudinally along the pipe 52 and rods 56 as they rotate.

A welding electrode 62 engages the wire 58 as it is wrapped on the rods 56 and provides a welding current that fuses the wire 58 and the rods 56. The welding electrode 62 is disc-shaped and rolls along the wire 58. To complete the circuit for welding, the rods 56 are grounded ahead of the wrapped wire 58 using a ground electrode assembly 70.

The ground electrode assembly 70 includes a plurality of contact assemblies 71 and a mounting plate 78. Each contact assembly 71 includes a contact 72 and a housing 74. Proper alignment and contact is needed for good welding. Moreover, optical sensors, controls, and the like are used to ensure that proper spacing is maintained between wraps of the wire 58 and that the wire 58 is extruded properly.

FIGS. 3A-3C show a wire-wrapped well screen 50 during stages of assembly. As before, the well screen 50 has a base pipe 52 that extends along the length of the wellscreen 50. Assembly begins with the base pipe 52 as shown in FIG. 3A, which can be manufactured and machined according to conventional practices. As shown, the base pipe 52 has a number of perforations 54 formed therein for passage of production fluid. The overall selection and layout of the perforations 54 depends on the particular implementation.

The rods 56 of the screen 50 are positioned around the base pipe 52 at desired spacings to form the desired longitudinal channels. Then, using a winding apparatus such as discussed previously with reference to FIGS. 2A-2B, a suitable length of the base pipe 52 is wrapped with wire 58 to form the screen 50 in one pass as shown in FIG. 3B. Typically, the size, shape, and spacing of the wire 58 remains relatively constant as the wire 58 is wrapped. Depending on the implementation and the different type of screen desired, any of these and other variables can be altered during the winding process so that the wire wrapping can change along its length.

As shown in FIG. 3B, the wire wrapping continues along the extent of the base pipe 52 to produce enough wire-wrapped screen length as needed. Finally, as shown in FIG. 3C, end rings 55 are then fit to ends of the screen 50 to complete the assembly.

Screens, such as the above well screen 50, can be used in many oilfield and industrial applications. Due to flow, temperature, pressure, abrasive material, etc., screens can be subject to erosion. Therefore, erosion resistance is an important attribute of screens, which affects the screens' application and longevity. Although erosion of screens is a problem that has been looked at through the years, a satisfactory solution has yet to be put forth for increasing the erosion resistance of wire-wrapped screens, such as used downhole in gravel pack and other completion systems.

Screens are available that have greater erosion resistance, but they may be unsuitable for applications where wire-wrap screens, such as discussed above, would be required. In short, wire-wrapped screens may be the best screen product to use in some applications, such as gravel pack completions. Unfortunately, erosion of wire-wrapped screens downhole can be a significant issue that is not an easy one to resolve.

The subject matter of the present disclosure is directed to overcoming, or at least reducing the effects of, one or more of the problems set forth above.

### SUMMARY OF THE DISCLOSURE

An embodiment of the present disclosure is a method of manufacturing or surface treating a wire-wrapped screen for use in a wellbore to improve the erosion resistance of the wire-wrapped screen. The method includes disposing the wire-wrapped screen on an axle and positioning the axle in a chamber. The chamber contains a source of erosion resistant surface coating material. The method also includes depositing the erosion resistant surface coating on at least a portion of the exterior of the wire-wrapped screen using a deposition process. The deposition process can use a physical vapor deposition process (PVD), such as a plasma glow discharge process, an electron ionization process, an ion source process and a magnetron sputtering process. Alternatively, the deposition process can use a thermal spraying process, such as a plasma spraying process, a detonation spraying process, a wire arc spraying process, an arc spraying process, a flame spraying process, and a high velocity oxy fuel spraying process. The erosion resistant surface coating can be a refractory hard material, diamond, complex carbide, nitride, boride, silicide, or Titanium Silicon Carbonnitride (TiSiCN).

Another embodiment of the present disclosure includes a method of manufacturing or surface treating a wire-wrapped screen for use in a wellbore to improve erosion resistance of the wire-wrapped screen. The method includes disposing the wire-wrapped screen on an axle and positioning an elastomer spray system proximate the wire-wrapped screen. The elastomer spray system has a deposition nozzle. The method further includes spraying an elastomer from the deposition nozzle onto the wire-wrapped screen such that the resulting elastomer coating coats at least a portion of the exterior surface of the wire-wrapped screen, thereby increasing the erosion resistance of the wire-wrapped screen.

The elastomer can be a combination of a rubber and a solvent, where the rubber can be a natural rubber, a synthetic rubber, or a nitrile rubber. The solvent can be Methyl Ethyl Ketone(MEK) and Toluene. The method can further include positioning a shroud outwardly radially from the wire-wrapped screen such that an opening in the shroud is positioned perpendicular to the elastomeric coating of the exterior surface of the wire-wrapped screen.

Another embodiment of the present disclosure includes a method of manufacturing or treating a wire-wrapped screen for use in a wellbore to improve erosion resistance of the wire-wrapped screen. The method includes enhancing erosion resistance of a wire for the wire-wrapped screen by treating at least a surface of the wire. The method then includes forming the wire-wrapped screen with the surface of the wire as the exterior of the screen by wrapping the wire about a mandrel.

Treating at least the surface of the wire can involves depositing an erosion resistant surface coating on at least a portion of the surface of the wire using a deposition process, such as a physical vapor deposition process (PVD) and a thermal spraying process. Alternatively, using the deposition process involves positioning an elastomeric spray system proximate the wire, where the elastomeric spray system has a deposition nozzle. Then, the deposition process involves spraying an elastomer from the deposition nozzle onto the wire such that the resulting elastomeric coating coats the at least portion of the surface of the wire, thereby increasing the erosion resistance of the wire-wrapped screen.

In yet another alternative, treating at least the surface of the wire involves surface treating the wire to induce compressive stresses or relieve tensile stresses such that at least the surface of the wire has a greater hardness. The surface treatment can be a mechanical process, such as peening, shot peening, and burnishing. Alternatively, the surface treatment can be a non-mechanical process, such as ultrasonic peening or laser peening.

Finally, treating at least the surface of the wire can involve applying a band of erosion resistant material to the surface of the wire and bonding the band to the surface of the wire. The band can be applied using a roller, an adhesive, or a resistance welding process, and the band can be bonded to the surface using a curing oven. For its part, the band of erosion resistant material can be a metallic material, a rubber material, or a combination of a metallic and rubber materials.

The foregoing summary is not intended to summarize each potential embodiment or every aspect of the present disclosure.

### BRIEF DESCRIPTION OF THE DRAWINGS

FIG. 1 illustrates a completion system having completion screen joints deployed in a borehole.

FIG. 2A shows a partially exposed side view of an apparatus for wrapping a base pipe and rods with wire.

FIG. 2B shows an end section of the apparatus of FIG. 2A.

FIGS. 3A-3C show a wire-wrapped screen during stages of assembly.

FIG. 4A illustrates a plasma glow discharge process for surface treating a wire-wrapped screen for erosion resistance according to the present disclosure.

FIG. 4B illustrates an electron impact ionization process for surface treating a wire-wrapped screen for erosion resistance according to the present disclosure.

FIG. 4C illustrates an ion source process for surface treating a wire-wrapped screen for erosion resistance according to the present disclosure.

FIG. 4D illustrates a magnetron sputtering process for surface treating a wire-wrapped screen for erosion resistance according to the present disclosure.

FIG. 4E shows a graph of testing of several wire wrapped screens.

FIG. 5 illustrates a spraying process for surface treating a wire-wrapped screen for erosion resistance according to the present disclosure.

FIG. 6A illustrates a flame spray technique for the spraying process of FIG. 5.

FIG. 6B illustrates an arc spray technique for the spraying process of FIG. 5.

FIG. 6C illustrates a plasma arc spray technique for the spraying process of FIG. 5.

FIG. 7 illustrates a deposition process 700 for surface treating a wire-wrapped screen for erosion resistance according to the present disclosure.

FIGS. 8A-8C illustrates a plasma arc spray process 800 for surface treating wire for erosion resistant prior to wrapping on a wire-wrapped screen according to the present disclosure.

FIGS. 9A-9C illustrate a surface treating deposition process for wire for erosion resistant prior to wrapping on a wire-wrapped screen according to the present disclosure.

FIGS. 10A-10C illustrates a process for coating wire with a coating material for erosion resistant prior to wrapping on a wire-wrapped screen according to the present disclosure.

FIGS. 11A-11C illustrates a process for coating wire with a rubber solution for erosion resistant prior to wrapping on a wire-wrapped screen according to the present disclosure.

FIGS. 12A-12C illustrates a process for covering wire with a band of material for erosion resistant prior to wrapping on a wire-wrapped screen according to the present disclosure.

FIGS. 13A-13C illustrates a process for burnishing wire for erosion resistant prior to wrapping on a wire-wrapped screen according to the present disclosure.

FIGS. 14A and 14B illustrate an outer shroud in conjunction with a wire-wrapped screen.

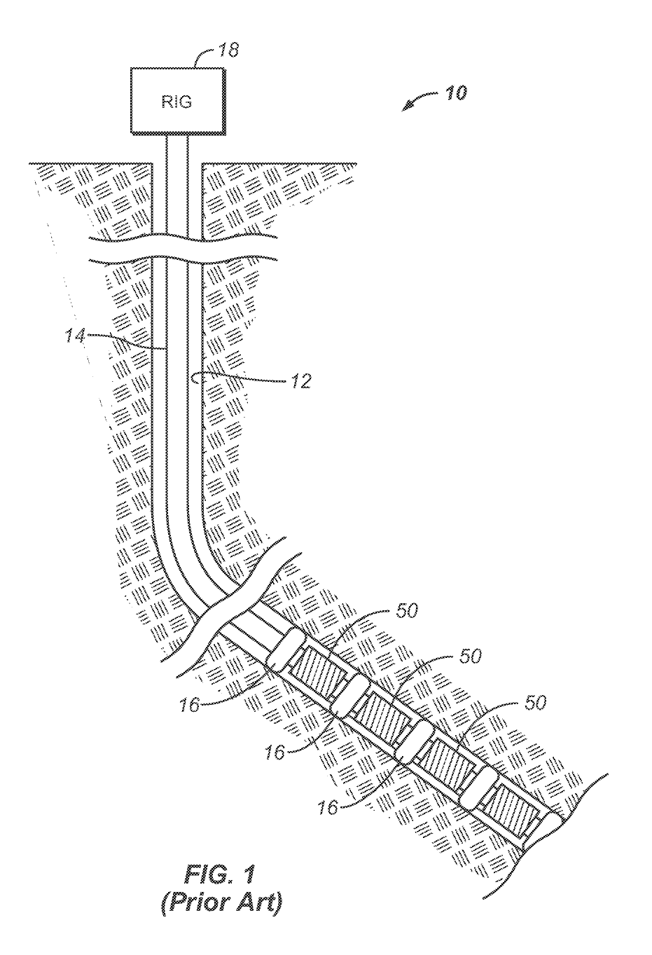

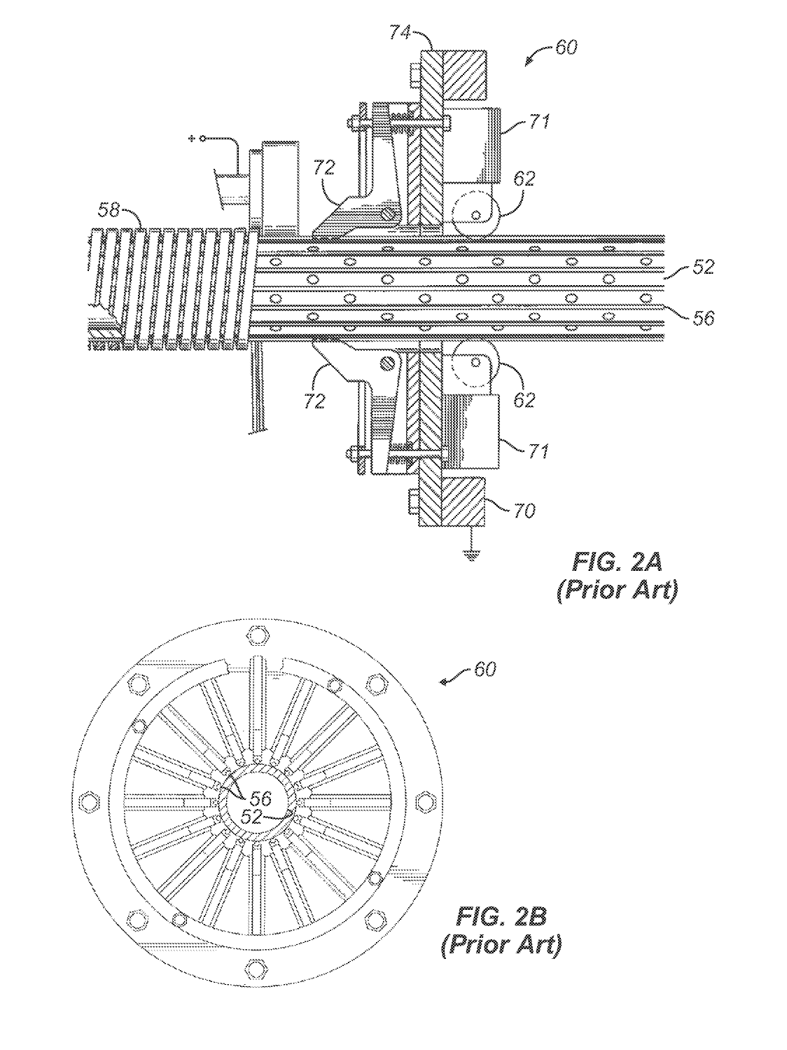

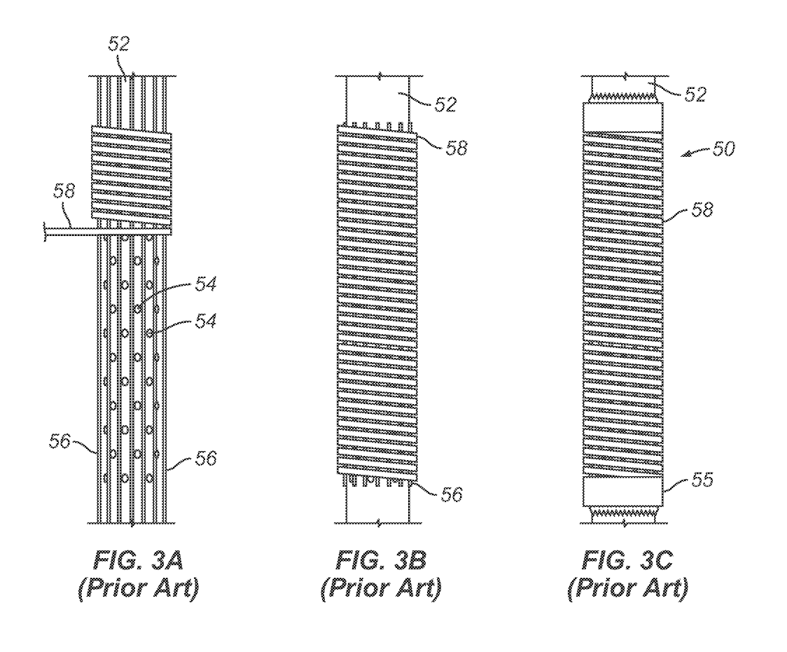

### DETAILED DESCRIPTION OF THE DISCLOSURE

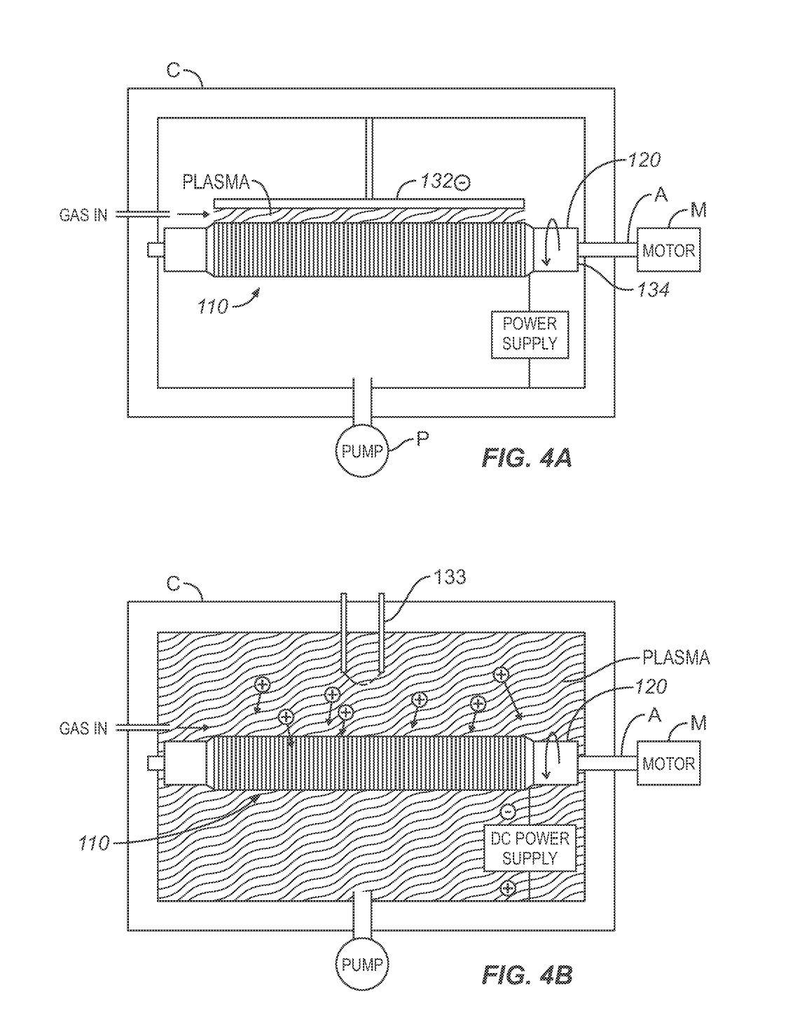

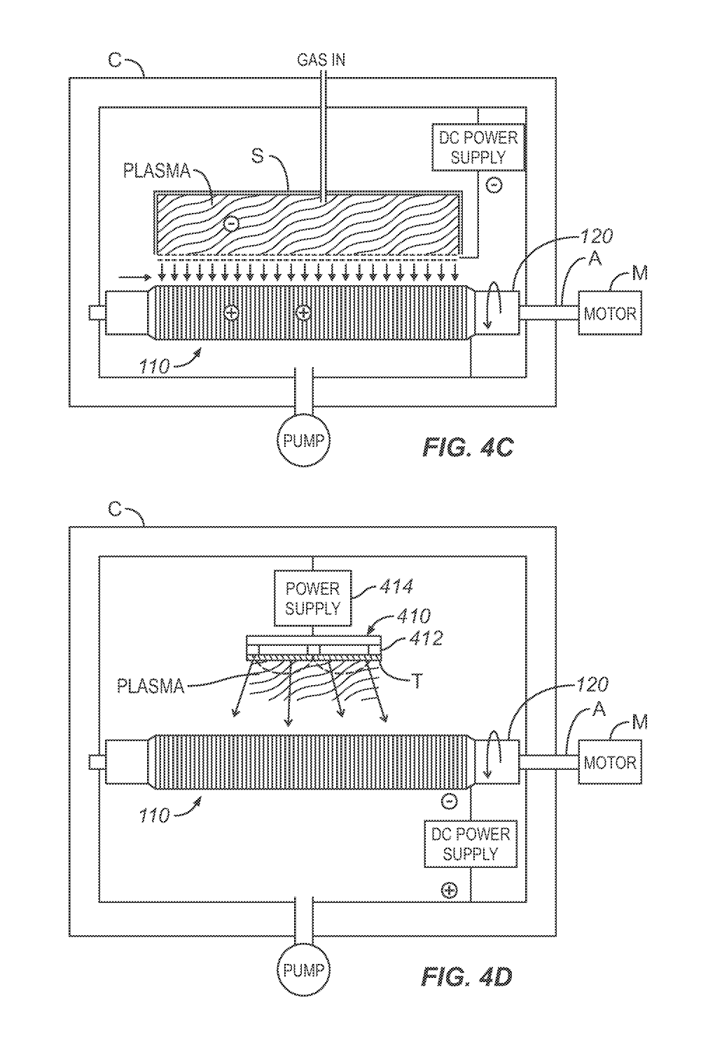

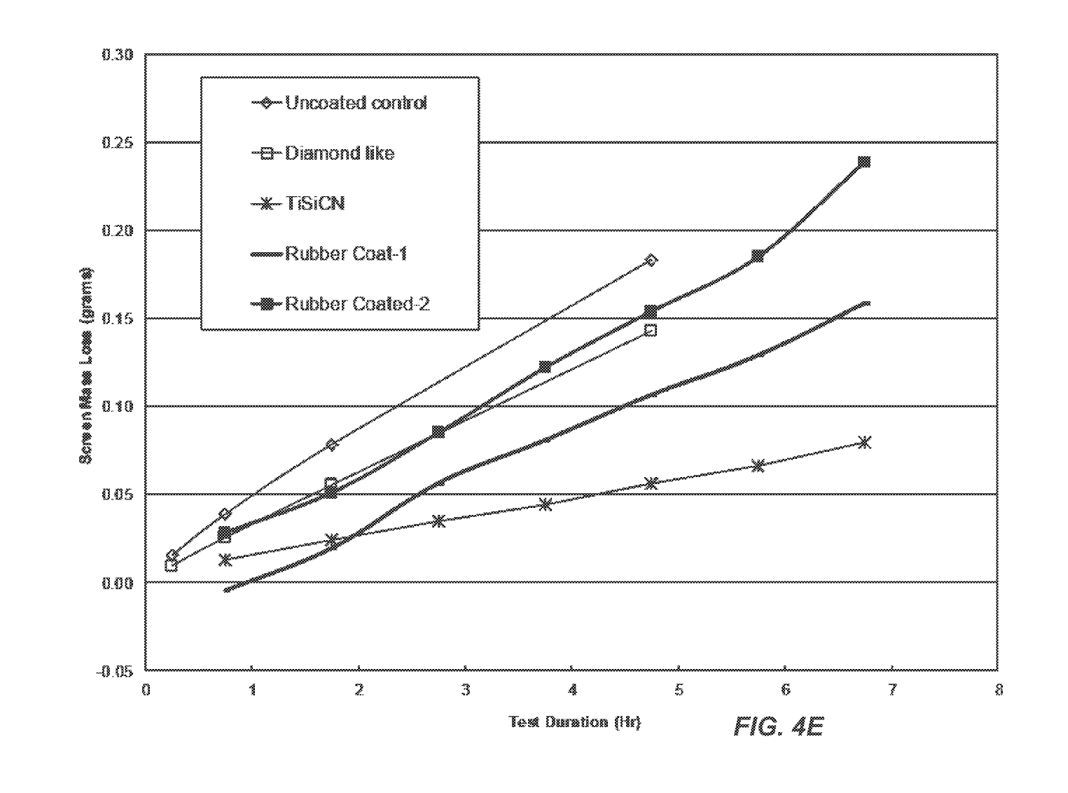

In FIGS. 4A-4D, a chamber C is shown for use in surface treating a wire-wrapped screen 110 for erosion resistance according to the present disclosure. The wire-wrapped screen 110 disposes on an axle in the chamber C. As shown, the wire-wrapped screen 110 can be a screen joint for a downhole completion, although any other type of wire-wrapped screen can be used.

In FIG. 4A, a plasma glow discharge process for surface treating the wire wrapped screen 110 for improved erosion resistance is shown. In the process of FIG. 4A as well as others disclosed below, a pump P draws a vacuum or builds a pressure in the chamber C depending on the coating process to be used. A source of erosion resistant coating material communicates with the chamber C and delivers the material for coating the wire-wrapped screen 110 for improving erosion resistance. Details related to a plasma generation process for surface coating the wire-wrapped screen 110 are provided below.

In general, the plasma glow discharge process of FIG. 4A is an example of a Physical Vapor Deposition or PVD process. Wire-wrapped screen 110 could be wrapped around a base pipe 120, or wire for the wrapped screen 110 can be initially wrapped around a mandrel (not shown) and then unwrapped and re-wrapped around the base pipe 120.

Either way, gas G introduced into chamber C contains ionized particles of an erosion resistant surface coating material. A plasma is generally created by RF(AC) or DC discharge between two electrodes (132, 134). Generally, the base pipe/mandrel 120 will carry a positive charge, and electrode 132 will carry a negative charge. Motor M may rotate wire-wrapped screen 110 about its longitudinal axis to enhance the substantially uniform distribution of the erosion resistant coatings on the surface of wire-wrapped screen 110.

In FIG. 4B, an electron impact ionization process is shown. In this process, gas G is fed into the chamber C, which has a source 133 of electrons. Electrons interact with the particles of plasma, which are then ionized. The ionized particles of erosion resistant surface coating are contained within the gaseous plasma. The ions interact with the wire-wrapped screen 110, which is subject to a DC power supply, and precipitate onto the negatively charged wire-wrapped screen 110. This process is also an example of a Physical Vapor Deposition (PVD). As before, a motor M may rotate wire-wrapped screen 110 about its longitudinal axis to enhance the substantially uniform distribution of the erosion resistant coatings on the surface of wire-wrapped screen 110.

In FIG. 4C, an ion source system is shown for depositing a thin film of erosion resistant material on the wire-wrapped screen 110. Again, the wire-wrapped screen 110 is disposed in a vacuum chamber C, and gas G is fed into the chamber C containing plasma. The ionized particles of erosion resistant surface coating are contained within the gaseous plasma. A portion or shroud S of the chamber C is subject to a DC power supply and is positioned relative to the wire-wrapped screen 110 to be treated. Again, a motor M may rotate wire-wrapped screen 110 about its longitudinal axis to enhance the substantially uniform distribution of the erosion resistant coatings on the surface of wire-wrapped screen 110. This process is yet another example of a Physical Vapor Deposition (PVD) process.

In FIG. 4D, a magnetron sputtering system 410 is shown for depositing a thin film of erosion resistant material on a wire-wrapped screen 110, such as the completed screen joint. Preferably, the screen 110 is disposed in a vacuum chamber C. Inside the chamber C, a magnetron 412 is coupled to a power supply 414 and has a target material T (i.e., the material to be deposited on the screen) disposed thereon. A negative charge is applied to the target T, and a plasma or glow discharge develops and starts the sputter deposition process. The plasma region generates positive charged gas ions, which are attracted to the negatively biased target material T at a very high speed. The resulting collision between the positive charged ion and the negatively biased target material causes material of the target T to be ejected, and the ejected material deposits on the surface of the screen 110 as a thin film because the ionized particles of erosion resistant surface coating are contained within the gaseous plasma, this process is also an example of a Physical Vapor Deposition (PVD_process.

It is preferable that the PVD processes described above occur when chamber C is substantially evacuated, i.e., a vacuum or partial pressure conditions are present in chamber C.

Examples of erosion resistant surface coatings include diamond, complex carbide, nitride, or boride coatings. Additionally, FIG. 4E shows a graph of testing of several wire wrapped screens. As seen in the graph, an uncoated control screen erodes most quickly. As also seen in the graph, a wire-wrapped screen that has been treated with Titanium Silicon Carbonitride (TiSiCN) would appear to best withstand erosion.

Moreover, the chart seen immediately below provides a summary of the laser coated erosion tests vs. a TISICN coated screen. The chart reflects that TiSiCN shows promise as an erosion resistant surface coating.

CHART

| | | | Parts Per | | | |
|---|---|---|---|---|---|---|
| Test | | | Million | Time | % | Sp. |
| # | Sample | Velocity | (PPM) | (hrs) | Loss | Wear |
| 5 | TISICN | 42 | 1340 | 0.75 | .009% | 8.51E−07 |
| | | ft/sec | | 1.75 | .017% | |
| | | | | 6.75 | .057% | |
| 10 | BB-14 | 40.6 | 1347 | 0.75 | .025% | 2.75E−6 |
| | | ft/sec | | 1.75 | .053% | |
| | | | | 6.75 | .172% | |
| 8 | RC-1, 63 | 41.7 | 1386 | 0.75 | .005% | 1.69E−06 |
| | H Wire | ft/sec | | 1.75 | .019% | |
| | | | | 6.75 | .154% | |
| 11 | RC-2 | 41.3 | 1307 | 0.75 | .02% | 2.68E−06 |
| | | ft/sec | | 1.75 | .035% | |
| | | | | 6.75 | .166% | |
| 1 | Uncoated | 40.5 | 1370 | 0.75 | .027% | 2.89E−06 |
| | | ft/sec | | 1.75 | .055% | |
| | | | | 4.75 | .129% | |

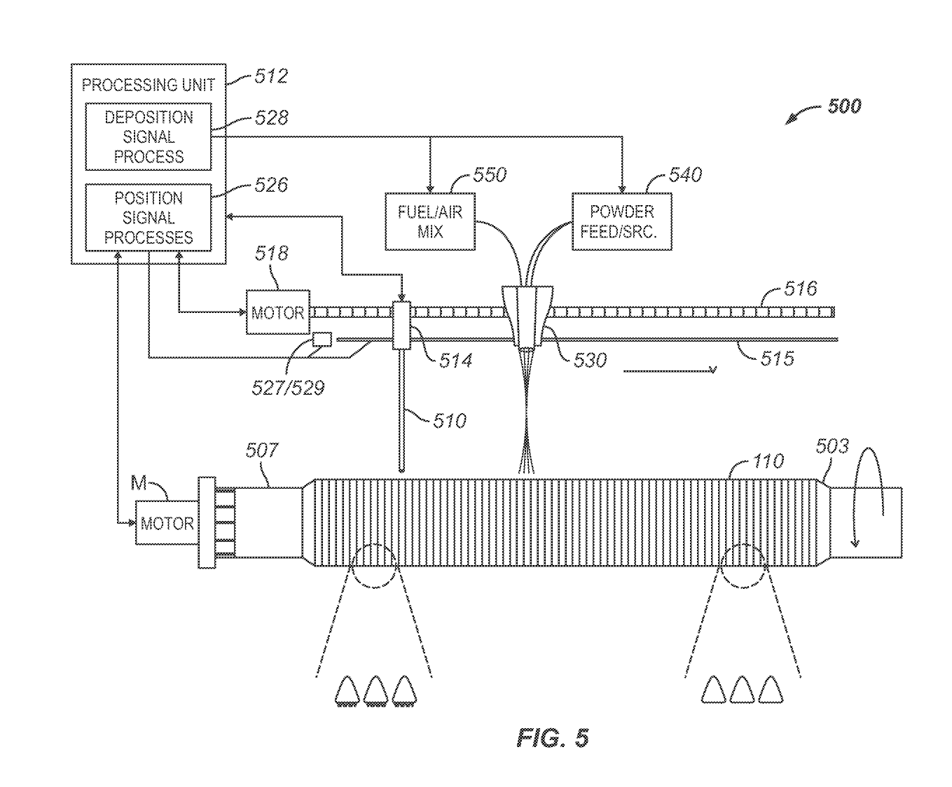

FIG. 5 illustrates a plasma deposition process for surface treating a wire-wrapped screen 110 for erosion resistance according to the present disclosure. FIG. 5 shows some of the hardware and software components for the process so a system 500 can automatically treat the screen surface.

As shown, the system 500 includes a processing unit 512, such as a computer, having a position signal process 526 and a deposition signal process 528. Operation of the various components of the deposition system 500 is controlled by the processing unit 512. Accordingly, the position signal process 526 is communicatively coupled to a carriage motor 518, a screen motor M, and sensors 510/527/529. The position signal processing component 526 may be implemented as an industrial I/O card with inputs suitable for reading encoder signals and outputs suitable for controlling motors. Likewise, the deposition signal process 528 is communicatively coupled to a powder feed source component 440 and a fuel/air mix component 550.

As shown, the system 500 can have at least one optical sensor 510, such as a camera or the like, which is positioned to have a field of view of the screen surface. The sensor 510 can be any suitable sensor, such as a well-known charge-coupled-device (CCD) camera, capable of capturing an image of the field of view with sufficient resolution to allow for the inspection of the treated screen surface as described herein. The sensor 110 outputs the captured image to the processing unit 512, which receives the image and processes the image to a format suitable for display or analysis.

Moreover, the optical sensor 510 preferably moves relative to the screen 110 so the plasma deposition process can be inspected along the length of the screen 110. For example, the sensor 510 may be mounted on a sensor carriage 514 that moves along a track 515 in response to rotating motion of a ball screw 516 driven by the carriage motor 518.

The screen 110 can be mounted on a screen holding member 507, such as an axle. Meanwhile, to rotate the screen 110 about the screen holding member 507, the processing unit 512 controls the screen motor 518 for driving a ball screw 516 via a signal generated by the position signal processing component 526.

The processing unit 512 determines via the position signal processing component 526 a position of a deposition carriage 530 via a signal generated by a position sensor, such as a rotary encoder 527 or linear encoder 529. To move the deposition carriage 530 at a desired rate along the screen 110, the processing unit 512 may, via the position signal processing component 526, generate signals to move the carriage 530 while monitoring signals indicative of the position of the carriage 530. As described below, the measured position of the carriage 530 relative to the screen 110 may be used to control the plasma deposition along the screen 110.

For some embodiments, the deposition operations may be performed in multiple passes to treat the surface of the screen 110. A counter can track the number of deposition passes. The screen 110 is positioned, for example, in the holding member 507. The deposition carriage 530 is moved relative to the screen 110, and its position relative to the screen 110 is measured for one or more such passes to track the deposition process. A determination is made (e.g., via signals from the rotary encoder 527 or linear encoder 529) as to whether the carriage 530 has reached the end of the screen 110 (or at least the last position of the screen 110 to be treated).

As illustrated in FIG. 5, rotation of the screen 110 may be accomplished by sending a signal to the screen motor M configured to rotate the screen holding member 507. For some embodiments, one or more reference marks 503 may be placed on the screen 110 (and/or the screen holding member 507) to indicate a rotational position of the screen 110. The processing unit 512 may be configured to detect the reference marks 503 as part of a captured image in order to determine position of the sensor 510 (and hence the deposition carriage 530). For other embodiments, a position sensor (not shown), such as a rotary encoder may be positioned to provide a signal indicative of the angular position of the screen holding member 507.

In either case, the screen 110 may be rotated during plasma deposition, and the operation may be repeated to make a resulting deposition with a desired thickness. In an effort to reduce deposition time, the processing unit 512 may monitor the relative positions of the carriage 530 and screen 110 while moving the carriage 530 and/or rotating the screen 110 in successively different directions as the carriage 530 is passed along the length of the screen 110.

For some embodiments, the screen 110 may be continually rotated as the carriage 530 is passed along the length of the screen 110. Alternatively, passes of the screen 110 can be made by the carriage 530 while the screen 110 is not rotated, but is instead rotated between passes. In general, movement of the carriage 530 may be synchronized with rotation of the screen 110.

The processing unit 512 also controls the plasma deposition process by controlling the feed of source deposition material of source component 540 and the fuel/air mix from fuel component 550 for generating plasma. The control of these components 540 and 550 is coordinated with the controlled movement of the deposition carriage 530 and the screen 110 to produce the desired erosion resistant treatment of the wire screen.

Although the carriage 530 is shown being moved along the length of the screen 110, it may be more practical in other implementations to maintain the deposition carriage 530 stationary and instead move the screen 110 laterally relative thereto. Likewise, although the screen 110 is shown being rotated, it may be more practical in other implementations to having the carriage 530 rotated around the outer surface of the screen 110, which remains stationary.

In general, as shown in FIG. 5, the deposition carriage 530 can use a spray system to coat the wires of the screen surface. A deposition material (e.g., powder) is fed into a deposition nozzle on the carriage 530. At the same time, a fuel/air mixture is fed into the nozzle. An electrode in the nozzle produces a plasma, which ionizes all or a substantial portion of the source deposition material. A combustion flame from the nozzle is positioned relative to the screen surface to coat the wires with the arc sprayed deposition material from the combustion flame.

A number of processes can be used to treat the surface of the wire screen 110. For example, a process of thermal spraying can be used. In thermal spraying, a coating material provided as wire or powder is heated until molten and propelled against the surface of the wire screen 110. The sprayed coating material bonds to the wire screen 110 and hardens as it cools into a continuous coating. To spray metal as the coating material, the thermal spray process can use a spray technique based on flame, arc, plasma, or a high velocity oxygen fuel (HVOF)—some of which are detailed below.

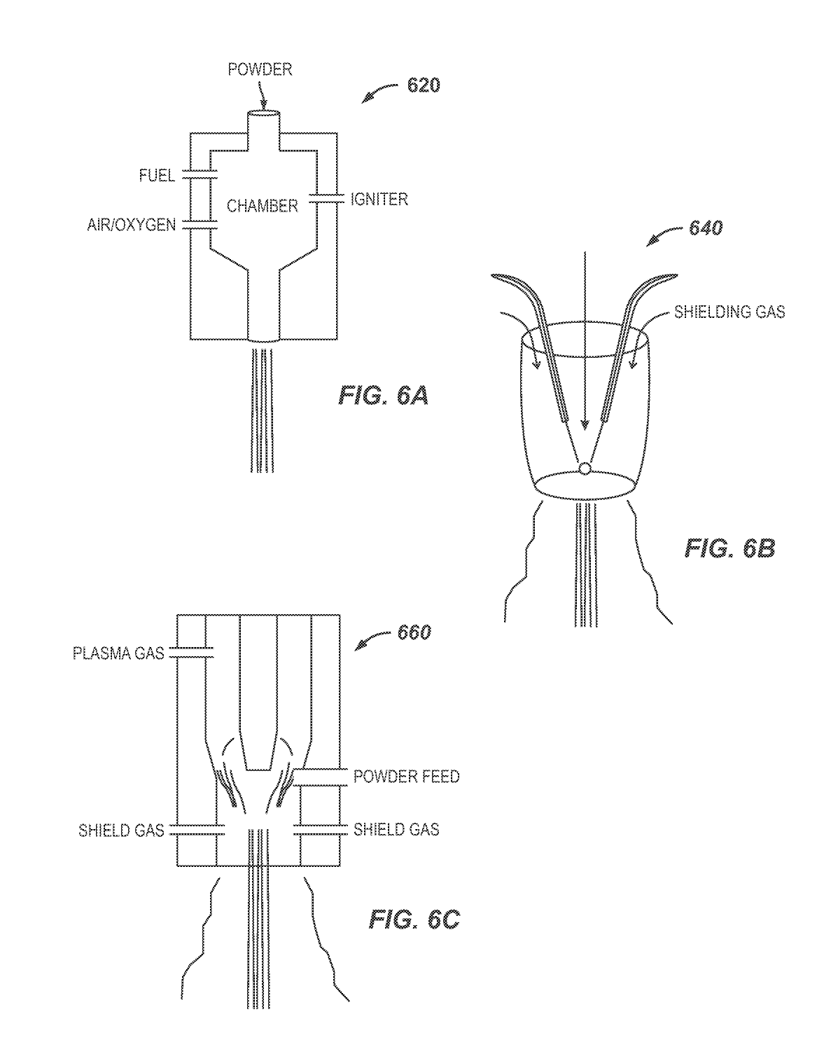

For example, FIG. 6A shows a flame spray technique 620 for the spraying process of FIG. 5. In the flame spray technique 620, a heat source may use a flame from a gas fuel (i.e., acetylene) and oxygen to heat coating material. When coating material is in the form of a wire, a spray nozzle uses compressed air to atomize the molten coating material and spray it onto the wire screen. If the coating material is in a powder form, the flame in the nozzle can spray the coating material onto the wire screen.

In another example, FIG. 6B illustrates a twin wire arc spray technique 640 for the spraying process of FIG. 5. In the arc spray technique 640, an electric arc is formed between two wires of the coating material being fed into the nozzle. The wires are electrically charged and form an electric arc that melts the material. The nozzle has compressed air or other shielding gas that passes through the nozzle and atomizes the molten wire to spray the material onto the wire screen (110).

In yet another example, FIG. 6C illustrates a plasma arc spray technique 660 for the spraying process of FIG. 5. In the plasma arc spraying technique 660, an electric arc inside the nozzle creates a plasma from an arc gas fed into the nozzle. Powder is fed into the plasma as it jets from the nozzle, and the molten material strikes the wire screen (110) at a high velocity.

Finally, in the high velocity oxygen fuel spray technique, a fuel and oxygen mixture is ignited, and the combustion gases accelerate through a nozzle. Powder injected into the flame is melted and projected against the wire screen, where the material hardens.

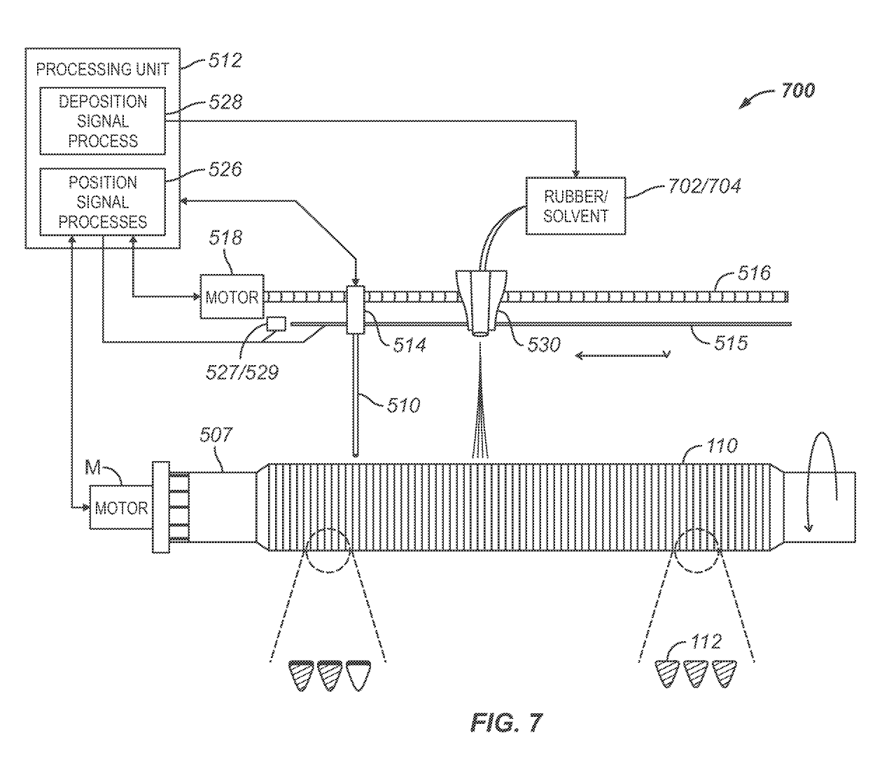

FIG. 7 illustrates a deposition process 700 for surface treating a wire-wrapped screen 110 for erosion resistance according to the present disclosure. Many of the components in FIG. 7 are similar to those described above with reference to FIG. 6 so that the same reference numbers are used and they are not repeated here.

In the deposition process of FIG. 7, a rubber and solvent combination 702/704 is sprayed from a nozzle on the carriage 530 for surface treating the wire-wrapped screen 110 for erosion resistance. The rubber material 702 is selected to produce a coating on the wire-wrapped screen 110 to increase the erosion resistance of the wire 112. Examples of the rubber material 702 include both natural and synthetic rubber, and the preferred rubber material 702 is believed to be nitrile rubber. Examples of the solvent 704 include MEK (Methyl Ethyl Ketone) and toluene. After surface treatment, the wire-wrapped screen 110 may be cured by heat or a combination of heat and pressure.

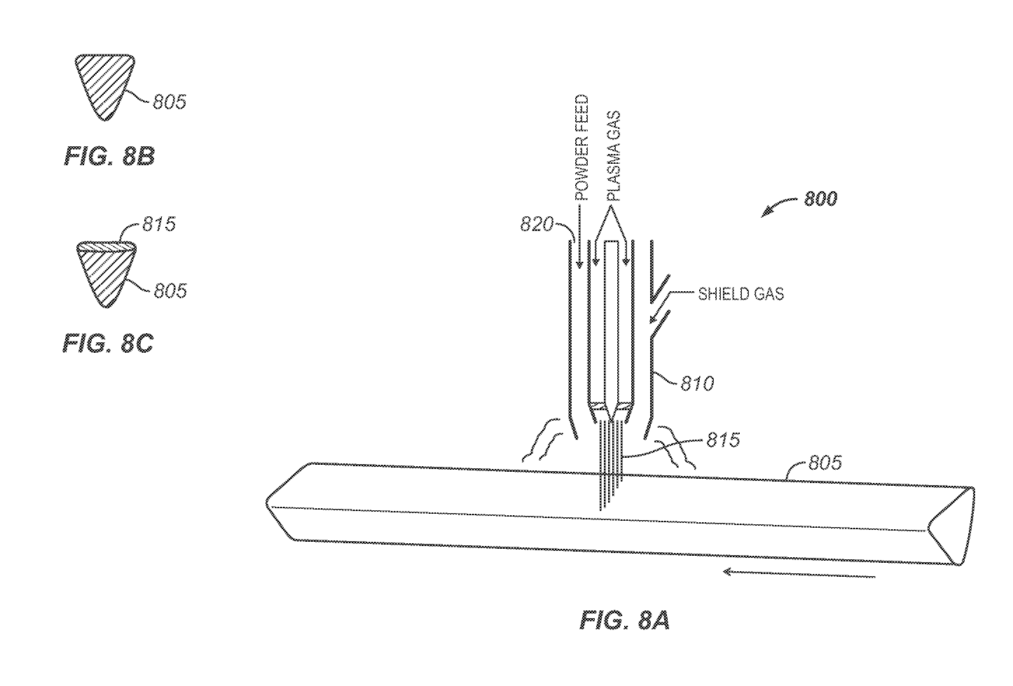

Rather than treat the surface of a completed screen joint as discussed above, wire for the wire-wrapped screen 110 can be first treated for erosion resistance and then wrapped to form the wire-wrapped screen 110 using winding techniques as discussed above. FIGS. 8A through 13 show several surface treating processes for the wire to be used to make a wire-wrapped screen 110.

FIGS. 8A-8C illustrates a plasma arc spray process for surface treating wire for erosion resistant prior to wrapping on a wire-wrapped screen according to the present disclosure. In FIG. 8A, for example, an arc spray deposition process 800 for surface treating wire for erosion resistant prior to wrapping on a wire-wrapped screen according to the present disclosure. The wire 805 is fed from a source (not shown), such a wire reel. The wire 805 may have been previously stored or may have been just manufactured. The deposition material 815 is applied with a deposition nozzle 810 directly to the outside surface of the wire 805. As used herein, this outside surface denotes the surface of the wire 805 intended to make the outside surface of the wire-wrapped screen (e.g., screen 110 depicted elsewhere).

The deposition nozzle 810 applies deposition material 815 to the outside surface of the wire 805. The deposition material 815 can come from a powder source 820 and can be deposited from the combustion flame from the nozzle 810 as the wire 805 moves along its length relative to the nozzle 810. The wire 805 after surface treatment can be directly wound around longitudinal ribs to form a wire-wrapped screen using a winding technique as disclosed above, or the wire 805 can be spooled for later using in wire wrapping.

FIG. 8B shows a cross-section of the wire 805 before treatment, and FIG. 8C shows a cross-section of the wire 805 after deposition material 815 has been applied to the outside surface.

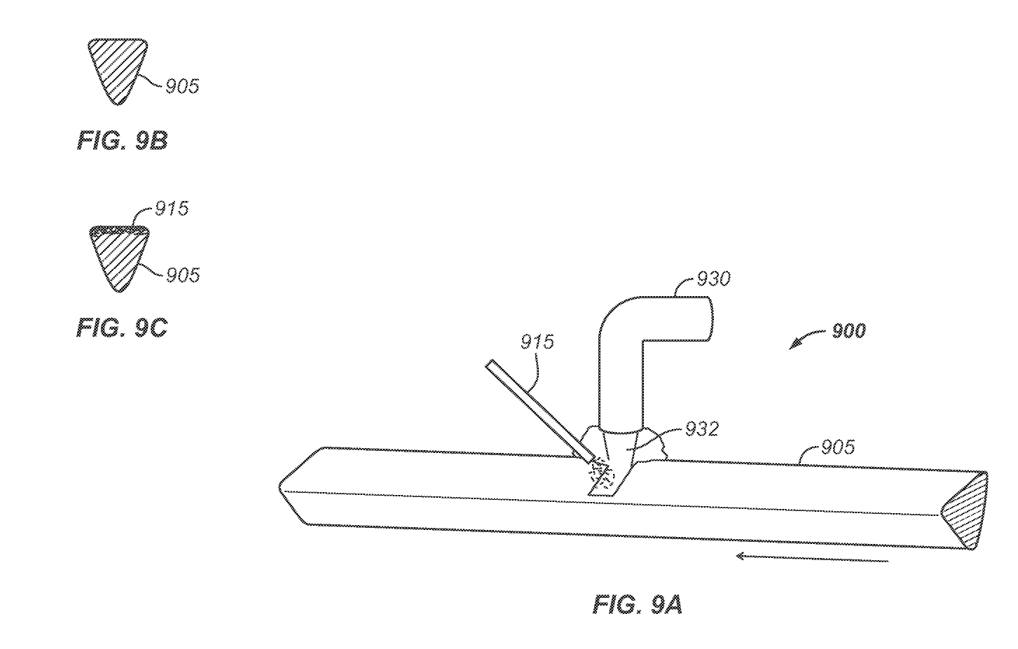

FIGS. 9A-9C illustrate another deposition process 900 for surface treating wire 905 for erosion resistant prior to wrapping on a wire-wrapped screen according to the present disclosure. In the deposition process 900 of FIG. 9A, the wire 905 is fed from a source (not shown), such a wire reel. The wire 905 may have been previously stored or may have been just manufactured. The deposition material 915 is applied directly to the outside surface of the wire 905. As used herein, this outside surface denotes the surface of the wire 905 intended to make the outside surface of the wire-wrapped screen.

A consumable powder or wire of deposition material 915 is fed to an area of the wire 905 being surface melted by a laser 930. The laser beam 932 can be directed to the wire 905 by a fiber optic cable or the like. The deposition material 915 at the surface melt area combines with the wire material to make a surface melt and alloy deposit. A shield gas can be used to control the process as the wire 915 is fed relative to the laser optic. Alternatively, the consumable could be added as a powder, either onto the wire surface or into the beam of the laser beam 932.

FIG. 9B shows a cross-section of the wire 905 before treatment, and FIG. 9C shows a cross-section of the wire 905 after treatment of the outside surface and deposition material 915 is deposited on wire 905.

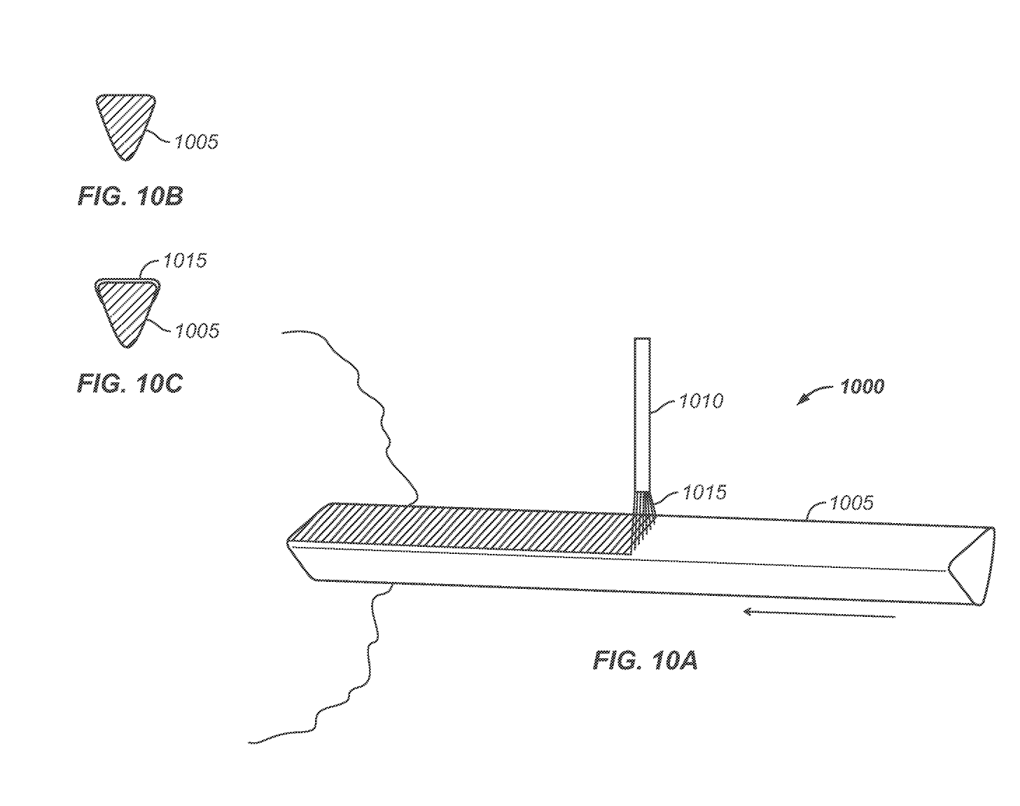

FIGS. 10A-10C illustrates a direct application process 1000 for coating wire with a coating material for erosion resistant prior to wrapping on a wire-wrapped screen according to the present disclosure. In FIG. 10A, the direct application process 1000 applies a rubber elastomer, a plastic, or another non-metallic coating 1015 to the wire 1005 for a wire wrapped screen. The wire 1005 is fed from a source (not shown), such a wire reel. The wire 1005 may have been previously stored or may have been just manufactured. The coating material 1015 is applied in a solution with a nozzle 1010 directly to the outside surface of the wire 1005. As used herein, this outside surface denotes the surface of the wire 1005 intended to make the outside surface of the wire-wrapped screen. After application of the coating material solution, the wire 1005 passes through a curing oven or system.

FIG. 10B shows a cross-section of the wire 1005 before coating, and FIG. 10C shows a cross-section of the wire 1005 after coating 1015 has been applied to the outside surface.

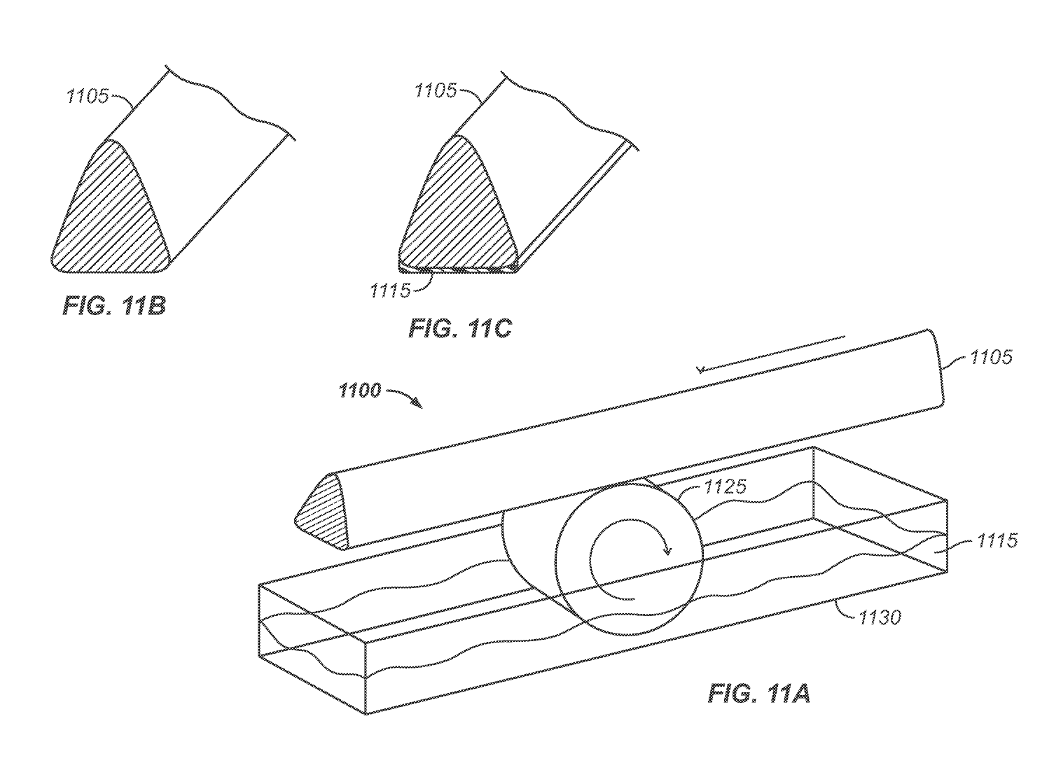

FIGS. 11A-11C illustrates another direct application process for coating a wire 1105 with a liquid containing coating material 1115 to improve erosion resistant prior to wrapping on a wire-wrapped screen according to the present disclosure. In FIG. 11A, the direct application process 1110 applies a rubber elastomer, a plastic, or another non-metallic coating to the wire 1105 for a wire wrapped screen. The wire 1105 is fed from a source (not shown), such a wire reel. The wire may have been previously stored or may have been just manufactured. As the wire 1105 is fed, it passes a roller 1125 disposed in a container containing a liquid 1115 that improves erosion resistance. A roller 1125 turns in the liquid 1115 with the movement of the wire 1105 and coats the outside surface of the wire 1105 (i.e., the surface of the wire to be exposed as the screen surface on a wire-wrapped screen) with the material of the liquid. As noted above, the liquid 1115 can be a rubber elastomer, plastic, or other non-metallic coating. The material may be heated in the container 1130 to produce the liquid 1115. Preferably, liquid 115 may be a slurry or the material may naturally form a slurry when produced, but may harden or solidify with time.

FIG. 11B shows a cross-section of the wire 1105 before coating, and FIG. 11C shows a cross-section of the wire after the liquid 1115 has coated the outside surface. After coating, the wire 1105 and the coating 1115 are passed through a curing oven or system.

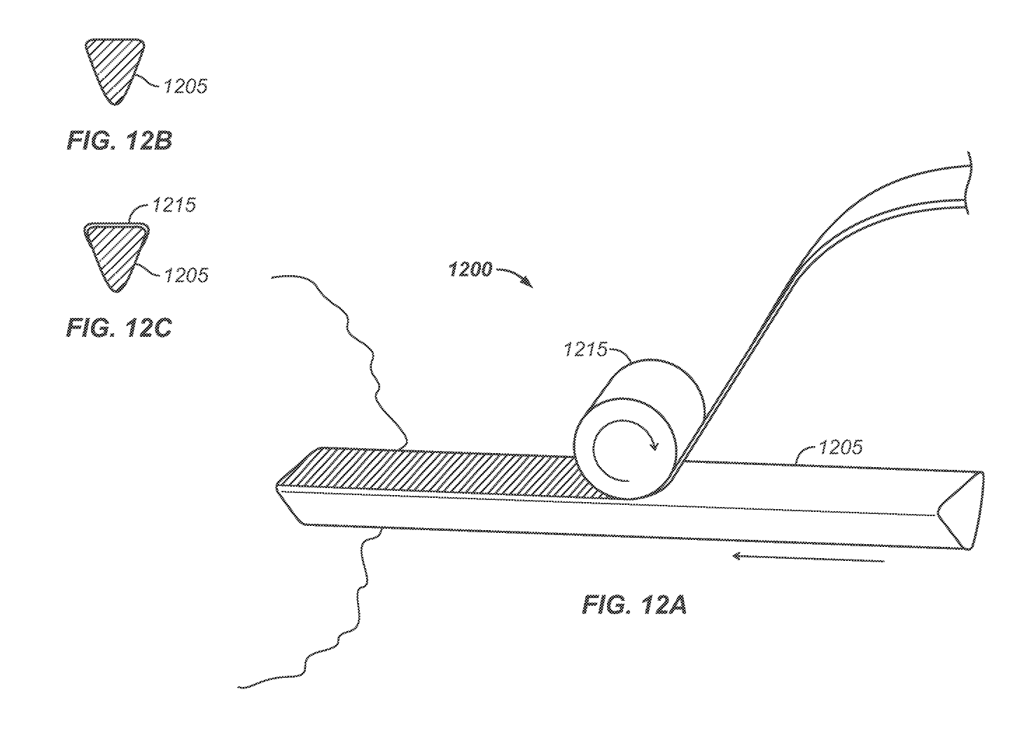

FIGS. 12A-12C illustrates yet another direct application process 1200 for covering wire with a band of material for erosion resistant prior to wrapping on a wire-wrapped screen according to the present disclosure. In FIG. 12A, the direct application process 1200 surface treats wire 1205 for erosion resistant prior to wrapping on a wire-wrapped screen according to the present disclosure. Here, as the wire 1205 is fed from a source (not shown), a tape or band of erosion resistant material 1215 is fed to the outside surface of the wire 1205 and applied thereto by a roller. An adhesive, heat, pressure, etc., may be used to initially hold the band to the wire, which then passes to an oven curing system to bond the material 1215 to wire 1205. In the alternative, the tape or band of material 1215 could be applied to wire 1205 with resistance welding or adhesion. Preferably, the material 1215 can be either metallic or rubber or a combination thereof.

FIG. 12B shows a cross-section of the wire 1205 before coating, and FIG. 12C shows a cross-section of the wire after material 1215 has been applied to wire 1205.

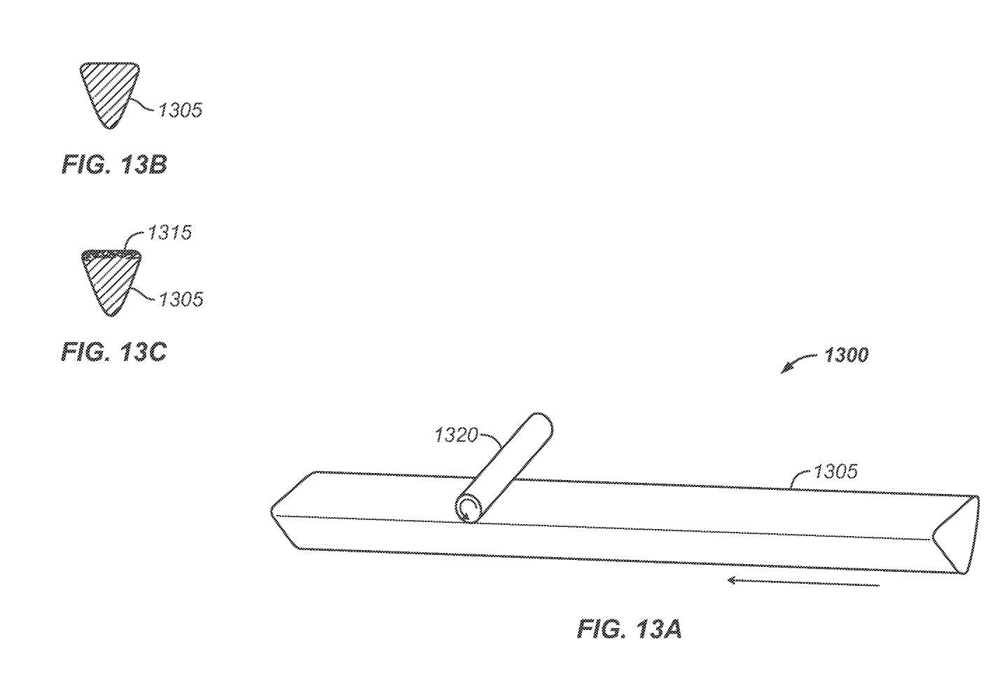

Finally, FIGS. 13A-13C illustrates a burnishing process 1300 for burnishing wire for erosion resistant prior to wrapping on a wire-wrapped screen according to the present disclosure. In FIG. 13A, the burnishing process 1300 surface treats wire 1305 for erosion resistant prior to wrapping on a wire-wrapped screen according to the present disclosure. In this process, an offset roller 1320 rotates on the outside surface of the wire 1305 as it is fed from a source (not shown) to a storage spool or to a wire wrapping machine. The roller burnishes and hardens the surface 1315 to make it more resistant to erosion. Other mechanical and non-mechanical processes could be used to surface treat wire 1305. For example, peening, shot peening, ultrasonic peening, and laser peening could be used to surface treat wire 1305.

FIG. 13B illustrates a cross-section of wire 1305 before treatment, and FIG. 13C illustrates a cross-section of wire 1305 after surface 1315 has been treated.

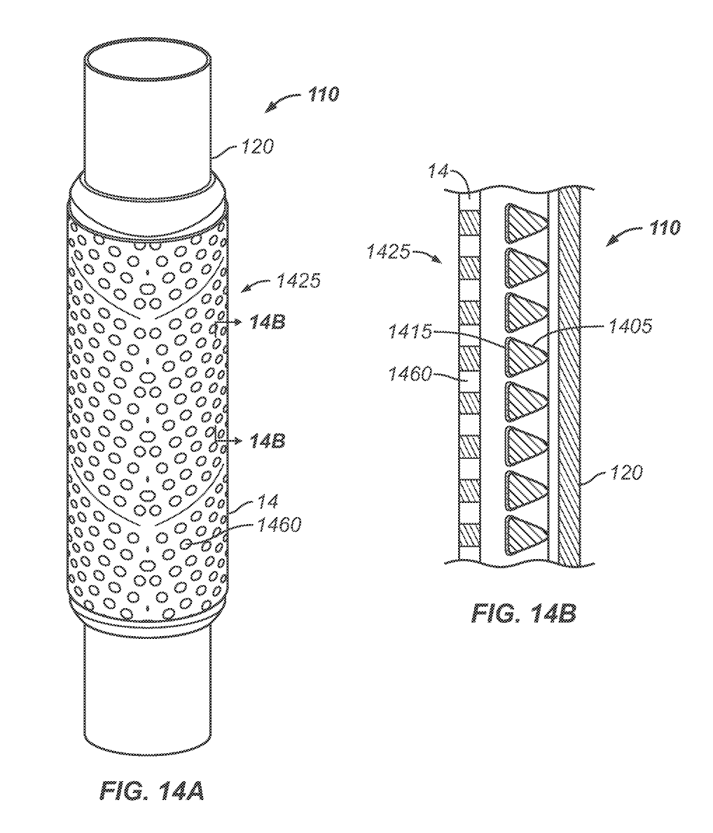

As noted above, either the wire itself is treated and then wrapped to form the wire-wrapped screen, or the surfaces of the wires already formed into the screen are treated. In some embodiments, it may be useful to have an additional barrier beyond the screen 110. For example, FIG. 14A and 14B illustrate an outer shroud 1425 used in conjunction with wire-wrapped shroud 110. In particular, FIG. 14A illustrates a perspective view of the wire-wrapped screen 110 having the outer shroud 1425 disposed thereon. FIG. 14B illustrates a cross-section view of the outer shroud 1425 and portion of the wire-wrapped screen 110.

Wire 1405 is coated with an elastomeric coating material 1415. Shroud 1425 has openings 1460 disposed therethrough. By using the perforated shroud 1425, it is believed that erosive material contained in a produced fluid will have less erosive effect, because erosive material will impact elastomeric coating material 1415 at a perpendicular or near perpendicular angle, and thereby allow the elastomeric coating material 1415 to reflect or “bounce” the erosive material outwardly. In other words, elastomeric coating material 1415 will reflect the erosive material. As seen in FIG. 14B, openings 1460 are preferably positioned longitudinally in relation to coating material 1415.

Although not discussed above, various preparatory steps and procedures may be needed to clean and prepare the surface of the screen or wire for treatment or application of erosion resistant material during manufacture, which would be appreciated by one skilled in the art having the benefit of the present disclosure. Moreover, various post treatment steps on the screen or wire may likewise be needed depending on the process used.

The foregoing description of preferred and other embodiments is not intended to limit or restrict the scope or applicability of the inventive concepts conceived of by the Applicants. It will be appreciated with the benefit of the present disclosure that features described above in accordance with any embodiment or aspect of the disclosed subject matter can be utilized, either alone or in combination, with any other described feature, in any other embodiment or aspect of the disclosed subject matter.

In exchange for disclosing the inventive concepts contained herein, the Applicants desire all patent rights afforded by the appended claims. Therefore, it is intended that the appended claims include all modifications and alterations to the full extent that they come within the scope of the following claims or the equivalents thereof.

What is claimed is:

1. A method of manufacturing a wire-wrapped screen for use in a wellbore to improve erosion resistance of the wire-wrapped screen, the method comprising:
(a) disposing the wire-wrapped screen on an axle;
(b) positioning the axle in a chamber, the chamber containing a source of erosion resistant surface coating; and
(c) depositing the erosion resistant surface coating on at least a portion of the exterior of the wire-wrapped screen using a deposition process.

2. The method of claim 1, wherein the deposition process is selected from the group consisting of a physical vapor deposition process (PVD) and a thermal spraying process.

3. The method of claim 2, wherein the erosion resistant surface coating is selected from the group consisting of refractory hard material, diamond, complex carbide, nitride, boride, silicide, and Titanium Silicon Carbonnitride (TiSiCN).

4. The method of claim 2, wherein the PVD process is selected from the group consisting of a plasma glow discharge process, an electron ionization process, an ion source process, and a magnetron sputtering process.

5. The method of claim 2, wherein the thermal spraying process is selected from the group consisting of a plasma spraying process, a detonation spraying process, a wire arc spraying, an arc spraying process, a flame spraying process, and a high velocity oxy fuel spraying process.

6. A method of manufacturing a wire-wrapped screen for use in a wellbore to improve erosion resistance of the wire-wrapped screen, the method comprising:
(a) disposing the wire-wrapped screen on an axle;
(b) positioning an elastomer spray system proximate the wire-wrapped screen, the elastomer spray system having a deposition nozzle; and
(c) coating at least a portion of an exterior surface of the wire-wrapped screen with an elastomer coating by spraying an elastomer from the deposition nozzle onto the wire-wrapped screen, thereby increasing the erosion resistance of the wire-wrapped screen.

7. The method of claim 6, wherein the elastomer is a combination of a rubber and a solvent.

8. The method of claim 7, wherein the rubber is selected from the group consisting of: a natural rubber, a synthetic rubber, and a nitrile rubber; and wherein the solvent is selected from the group consisting of: Methyl Ethyl Ketone(MEK) and Toluene.

9. The method of claim 6, further comprising:
(d) positioning a shroud outwardly radially from the wire-wrapped screen such that an opening in the shroud is positioned perpendicular to the elastomeric coating of the exterior surface of the wire-wrapped screen.

10. A method of manufacturing a wire-wrapped screen for use in a wellbore to improve erosion resistance of the wire-wrapped screen, the method comprising:
(a) enhancing erosion resistance of a wire for the wire-wrapped screen by treating at least a surface of the wire; and
(b) forming the wire-wrapped screen with the surface of the wire as the exterior of the screen by wrapping the wire about a mandrel.

11. The method of claim 10, wherein treating at least the surface of the wire comprises depositing an erosion resistant surface coating on at least a portion of the surface of the wire using a deposition process.

12. The method of claim 11, wherein the erosion resistant surface coating is selected from the group consisting of refractory hard material, diamond, complex carbide, nitride, boride, silicide, and Titanium Silicon Carbonnitride (TiSiCN).

13. The method of claim 11, wherein the deposition process is selected from the group consisting of a physical vapor deposition process (PVD) and a thermal spraying process.

14. The method of claim 13, wherein the PVD process is selected from the group of a plasma glow discharge process, an electron ionization process, an ion source process and a magnetron sputtering process.

15. The method of claim 13, wherein the thermal spraying process is selected from the group consisting of a plasma spraying process, a detonation spraying process, a wire arc spraying process, an arc spraying process, a flame spraying process, and a high velocity oxy fuel spraying process.

16. The method of claim 11, wherein depositing the erosion resistant surface coating on at least the portion of the surface of the wire using the deposition process comprises:
(a) positioning an elastomeric spray system proximate the wire, the elastomeric spray system having a deposition nozzle; and
(b) spraying an elastomer from the deposition nozzle onto the wire such that the resulting elastomeric coating coats the at least portion of the surface of the wire, thereby increasing the erosion resistance of the wire-wrapped screen.

17. The method of claim 16, wherein the elastomer is a combination of a rubber and a solvent.

18. The method of claim 17 wherein the rubber is selected from the group consisting of: natural rubber, synthetic rubber, and nitrile rubber; and wherein the solvent material is selected from the group consisting of: Methyl Ethyl Ketone(MEK) and Toluene.

19. The method of claim 10, wherein treating at least the surface of the wire comprises surface treating the wire to induce compressive stresses or relieve tensile stresses such that at least the surface of the wire has a greater hardness.

20. The method of claim 19, wherein the surface treating comprises a mechanical process selected from the group consisting of peening, shot peening and burnishing.

21. The method of claim 19, wherein the surface treating comprises a non-mechanical process selected from the group consisting of ultrasonic peening and laser peening.

22. The method of claim 10, wherein treating at least the surface of the wire comprises:
(a) applying a band of erosion resistant material to the surface of the wire; and
(b) bonding the band of erosion resistant material to the surface of the wire.

23. The method of claim 22, wherein applying the band of the erosion resistant material to the surface of the wire comprises using a roller, an adhesive, or a resistance welding process.

24. The method of claim 22, wherein bonding the band of the erosion resistant material to the surface of the wire comprises using a curing oven.

25. The method of claim 22, wherein the band of erosion resistant material is a metallic material, a rubber material, or a combination of a metallic and rubber materials.
